(19) United States
(12) Patent Application Publication
(10) Pub. No.: US 2011/0002351 A1
(43) Pub. Date: Jan. 6, 2011

(54) SEMICONDUCTOR LASER DEVICE

(75) Inventor: Kimio Shigihara, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/616,816

(22) Filed: Nov. 12, 2009

(30) Foreign Application Priority Data
Jul. 1, 2009 (JP) 2009-157115

(51) Int. Cl. H01S 5/00

(52) U.S. Cl. 372/45.01

(57) ABSTRACT

A semiconductor laser device includes: a p-type cladding layer; a p-type cladding layer guide layer; an active layer; an n-type cladding layer guide layer; and an n-type cladding layer, in which each of the p-type and n-type cladding layer guide layers is undoped or close to undoped, the sum of the thickness of the p-type cladding layer guide layer and the thickness of the n-type cladding layer guide layer is at least 200 nm, and both of (i) the difference between the band gap energy of the p-type cladding layer guide layer and the band gap energy of the active layer, and (ii) the difference between the band gap energy of the n-type cladding layer guide layer and the band gap energy of the active layer do not exceed 0.3 eV.

### BACKGROUND OF THE INVENTION

1. Field of the Invention

The present invention relates to a semiconductor laser device, and more particularly, to a semiconductor laser device for excitation light source, such as a solid state laser including an Nd-doped yttrium aluminum garnet (YAG) (Nd:YAG) laser and an Yb-doped YAG (Yb:YAG) laser, an Yb-doped fiber laser, an Er-doped fiber amplifier, or the like.

2. Description of the Related Art

In order to provide a semiconductor laser device capable of high power operation, conventional technologies have adopted a structure in which a GaAsP active layer is sandwiched between AlₓGa₁₋ₓAs optical guide layers each having an x of an aluminum composition 0.45 or 0.65, to thereby realize high power operation (see, for example, J. Sebastian, et. al., “High-Power 810-nm GaAsP-AlGaAs Diode Lasers With Narrow Beam Divergence”, IEEE Journal on Selected Topics in Quantum Electronics, vol. 7, No. 2, March/April 2001, pp. 334-339). A difference between a band gap energy of the active layer and a band gap energy of the optical guide layer corresponds to approximately 0.45 eV in the case where the layer thickness x is 0.45, and corresponds to approximately 0.72 eV in the case where the layer thickness x is 0.65.

In recent years, there is an increasing need for a semiconductor laser device in which electric conversion efficiency is improved for reducing power consumption. According to the above-mentioned conventional technology, the guide layers are increased in thickness so as to suppress light absorption, to thereby improve slope efficiency, which produces a certain effect of improving electric conversion efficiency. However, there has been a problem that the improvement in electric conversion efficiency is not sufficiently attained by the conventional technology.

### SUMMARY OF THE INVENTION

The present invention has been made to solve the above-mentioned problem, and therefore it is an object of the invention to provide a semiconductor laser device which is capable of high power operation while allowing electric conversion efficiency thereof to be improved, to thereby realize lower power consumption.

According to the present invention, there is provided a semiconductor laser device including at least: a p-type cladding layer; a p-type cladding layer side guide layer; an active layer; an n-type cladding layer side guide layer; and an n-type cladding layer, in which each of the p-type cladding layer side guide layer and the n-type cladding layer side guide layer is in one of an undoped state or a doped state close to the undoped state, a sum of a thickness of the p-type cladding layer side guide layer and a thickness of the n-type cladding layer side guide layer is set to 200 nm or more, and both of a difference between a band gap energy of the p-type cladding layer side guide layer and a band gap energy of the active layer and a difference between a band gap energy of the n-type cladding layer side guide layer and the band gap energy of the active layer are set to 0.3 eV or less.

The semiconductor laser device according to the present invention includes at least: the p-type cladding layer; the p-type cladding layer side guide layer; the active layer; the n-type cladding layer side guide layer; and the n-type cladding layer, in which each of the p-type cladding layer side guide layer and the n-type cladding layer side guide layer is in one of an undoped state or a doped state close to the undoped state, the sum of the thickness of the p-type cladding layer side guide layer and the thickness of the n-type cladding layer side guide layer is set to 200 nm or more, and both of the difference between the band gap energy of the p-type cladding layer side guide layer and the band gap energy of the active layer and the difference between the band gap energy of the n-type cladding layer side guide layer and the band gap energy of the active layer are set to 0.3 eV or less. As a result, the semiconductor laser device is capable of high power operation while allowing electric conversion efficiency thereof to be improved, to thereby realize lower power consumption.

### BRIEF DESCRIPTION OF THE DRAWINGS

In the accompanying drawings:

FIG. 1 is a perspective view illustrating a semiconductor laser device according to Embodiment 1 of the present invention;

FIG. 2 is a graph for illustrating a relationship between an operating voltage and a guide layer thickness in the semiconductor laser device according to Embodiment 1 of the present invention;

FIG. 3 is a graph for illustrating voltage-current characteristics of the semiconductor laser device according to Embodiment 1 of the present invention;

FIG. 4 is a perspective view illustrating a semiconductor laser device according to Embodiment 2 of the present invention; and

FIG. 5 is a graph for illustrating a relationship between an operating voltage and a guide layer thickness in the semiconductor laser device according to Embodiment 2 of the present invention.

### DETAILED DESCRIPTION OF THE PREFERRED EMBODIMENTS

### Embodiment 1

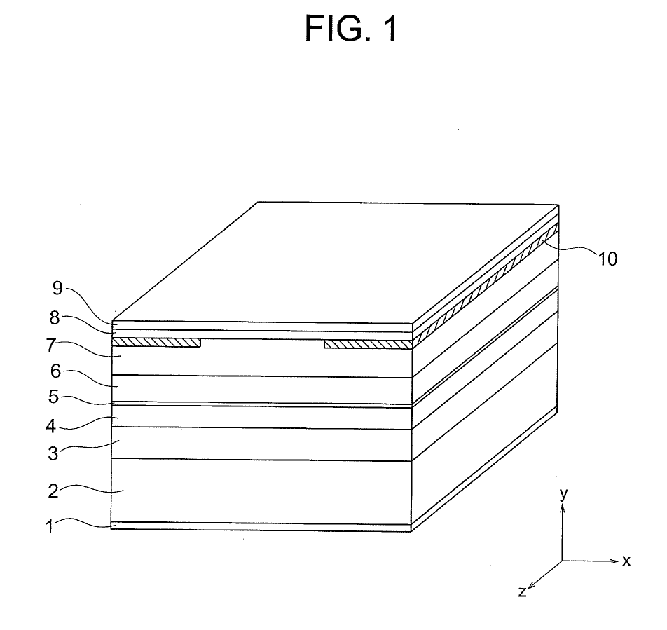

FIG. 1 is a perspective view illustrating a semiconductor laser device having an oscillation wavelength of approximately 810 nm according to Embodiment 1 of the present invention. In FIG. 1, the semiconductor laser device includes an n-type electrode 1, an n-type GaAs substrate 2, an n-type Al_{0.15}Ga_{0.35}In_{0.5}P cladding layer 3 (with a layer thickness of 1.5 μm) (hereinafter referred to as n-type cladding layer 3), an n-type cladding layer side In₁₋ₓGaₓAs_{y}P_{1-y} guide layer 4 (with a layer thickness of tn) (hereinafter referred to as n-type cladding layer side guide layer 4), a GaAs_{1-z}P_{z} active layer 5 (with a layer thickness of 12 nm) (hereinafter referred to as active layer 5), a p-type cladding layer side In₁₋ₓGaₓAs_{y}P_{1-y} guide layer 6 (with a layer thickness of tp) (hereinafter referred to as p-type cladding layer side guide layer 6), a p-type Al_{0.15}Ga_{0.35}In_{0.5}P cladding layer 7 (with a layer thickness of 1.5 μm) (hereinafter referred to as p-type cladding layer 7), a p-type GaAs contact layer 8, a p-type electrode 9, and a proton injection region 10. Note that the n-type cladding layer side guide layer 4 and the p-type cladding layer side guide layer 6 are not intentionally doped in the course of crystal growth and wafer processing, so as to be in an undoped state or a doped state close to the undoped state.

An operation of the semiconductor laser device is described. A forward bias is applied across the semiconductor laser device of FIG. 1, to thereby inject electrons into the active layer 5 from the n-type cladding layer 3 through the n-type cladding layer side guide layer 4, and inject holes into the active layer 5 from the p-type cladding layer 7 through the p-type cladding layer side guide layer 6. In the active layer 5, electrons and holes are recombined with each other, resulting in emission.

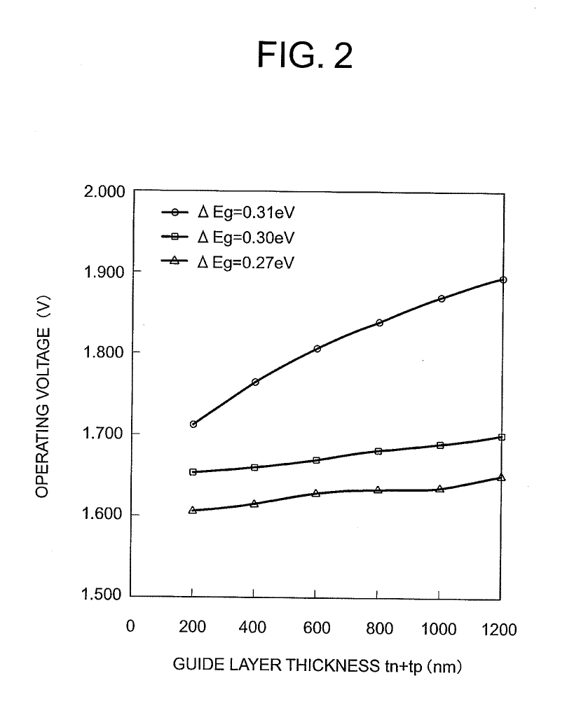

To clarify effects of the present invention, operating voltage is determined. The determination is carried out in the following manner. An operating voltage with an injection current of 24 mA is determined in each case where a P composition ratio z of the active layer 5 and an As composition ratio y of the n-type and p-type cladding layer side guide layers 4 and 6 are varied to change a band gap energy difference ΔEg, which is a difference between a band gap energy of the active layer 5 and a band gap energy of the n-type and p-type cladding layer side guide layers 4 and 6, while the layer thickness tn of the n-type cladding layer side guide layer 4 and the layer thickness tp of the p-type cladding layer side guide layer 6 are varied. Results of the determination are illustrated in FIG. 2. In FIG. 2, a horizontal axis indicates a sum of the layer thickness to and the layer thickness tp (tn+tp (nm)) and a vertical axis indicates an operating voltage (v). Note that a stripe width and a cavity length are respectively set to 1 μm and 1,200 μm. It is found from FIG. 2 that when the band gap energy difference ΔEg is 0.3 eV or less, the operating voltage itself becomes lower, and the operating voltage hardly depends on the sum (tn+tp) of the layer thicknesses of the guide layers 4 and 6. It is also found from FIG. 2 that when ΔEg is 0.31 eV (that is, when ΔEg exceeds 0.30 eV), the operating voltage itself becomes higher, and dependence on the sum (tn+tp) of the layer thicknesses of the n-type and p-type cladding layer side guide layers 4 and 6 is increased, so that the operating voltage becomes higher as the layer thicknesses tn and tp of the n-type and p-type cladding layer side guide layers 4 and 6 are increased. In Embodiment 1, because the n-type cladding layer side guide layer 4 and the p-type cladding layer side guide layer 6 are similar to each other, the difference ΔEg between the band gap energy of the active layer 5 and the band gap energy of the n-type cladding layer side guide layer 4 and the difference ΔEg between the band gap energy of the active layer 5 and the band gap energy of the p-type cladding layer side guide layer 6 are equal to each other. Note that even when the n-type cladding layer side guide layer 4 and the p-type cladding layer side guide layer 6 are formed of different materials or compositions, similar effects are achieved as long as both of the difference ΔEg between the band gap energy of the active layer 5 and the band gap energy of the n-type cladding layer side guide layer 4 and the difference ΔEg between the band gap energy of the active layer 5 and the band gap energy of the p-type cladding layer side guide layer 6 are set to 0.3 eV or less.

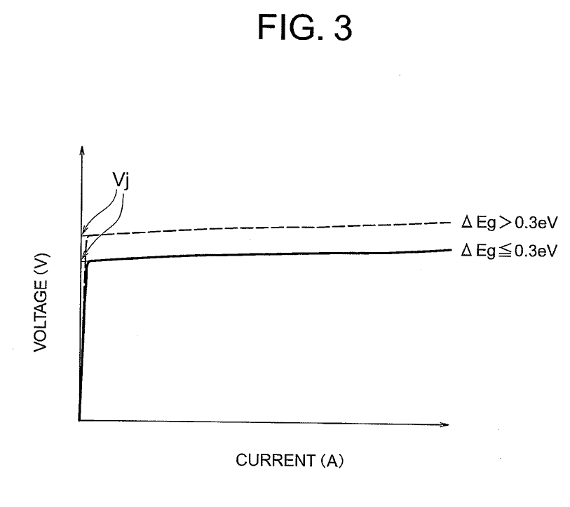

FIG. 3 is a graph schematically illustrating voltage-current characteristics in the case where the band gap energy difference ΔEg is 0.3 eV or less and the case where the band gap energy difference ΔEg exceeds 0.3 eV. As a result of the detailed study, it was found that when ΔEg exceeds 0.3 eV (ΔEg>0.3 eV), a turn-on voltage Vj in the voltage-current characteristics becomes higher, as illustrated in FIG. 3. It was also revealed that a value of the turn-on voltage Vj becomes higher as ΔEg increases by exceeding 0.3 eV. This may result from the fact that a quasi Fermi level increases as ΔEg increases, because some of carriers including electrons and holes need to remain within the n-type and p-type cladding layer side guide layers 4 and 6 as well during the operation of the semiconductor laser device.

On the other hand, when ΔEg is 0.3 eV or less, the turn-on voltage Vj exhibits a saturation tendency, in which the turn-on voltage Vj is less likely to be significantly lowered even when ΔEg is set lower. This is because, when ΔEg is as small as 0.3 eV or less, carriers are likely to be accumulated within the n-type and p-type cladding layer side guide layers 4 and 6, which means that the need for increasing the quasi Fermi level is eliminated. In this case, the quasi Fermi level and the turn-on voltage Vj are determined depending on carriers accumulated within the active layer 5. Taking the need for effectively confining carriers within the active layer 5 into consideration, a lower limit of the band gap energy difference ΔEg is approximately 0.1 eV.

Note that when the sum (tn+tp) of the layer thicknesses of the n-type and p-type cladding layer side guide layers 4 and 6 is reduced to 200 nm or less, carriers are likely to be accumulated within the n-type and p-type cladding layer side guide layers 4 and 6, and accordingly the turn-on voltage Vj exhibits a tendency to be lower. However, when the sum (tn+tp) of the layer thicknesses of the n-type and p-type cladding layer side guide layers 4 and 6 is reduced to 200 nm or less, a large amount of light penetrates into the n-type and p-type cladding layers 3 and 7 so as to be affected by free carrier absorption in the n-type and p-type cladding layers 3 and 7, which is not preferable. From a viewpoint that 80% or more of light should be confined to the n-type and p-type cladding layer side guide layers 4 and 6, which are in an undoped state, to thereby reduce the influence of free carrier absorption in the n-type and p-type cladding layers 3 and 7, it is preferable that the sum (tn+tp) of the layer thicknesses of the n-type and p-type cladding layer side guide layers 4 and 6 be set to be half an oscillation wavelength or more, that is, 405 nm or more. Note that an upper limit of the sum (tn+tp) of the layer thicknesses of the n-type and p-type cladding layer side guide layers 4 and 6 is several pm, which corresponds to a diffusion length of carriers.

As described above, in the semiconductor laser device according to Embodiment 1 of the present invention, the n-type and p-type cladding layer side guide layers 4 and 6 are not intentionally doped so as to be in an undoped state or a doped state close to the undoped state, and the sum of the layer thicknesses of the n-type and p-type cladding layer side guide layers 4 and 6 is set to 200 nm or more. Accordingly, higher level of light intensity may be maintained in the n-type and p-type cladding layer side guide layers 4 and 6, which makes it possible to reduce the free carrier absorption in the n-type and p-type cladding layers 3 and 7. As a result, it becomes possible to achieve improvement of slope efficiency. Besides, the band gap energy difference ΔEg, which is the difference between the band gap energy of the n-type and p-type cladding layer side guide layers 4 and 6 and the band gap energy of the active layer 5 is set to 0.3 eV or less, which makes it possible to lower the turn-on voltage Vj in the voltage-current characteristics in the case where a forward current is caused to flow through the semiconductor laser device. It also becomes possible to achieve reduction of the operating voltage. With the above-mentioned structure, it becomes possible to improve electric conversion efficiency of the semiconductor laser device.

### Embodiment 2

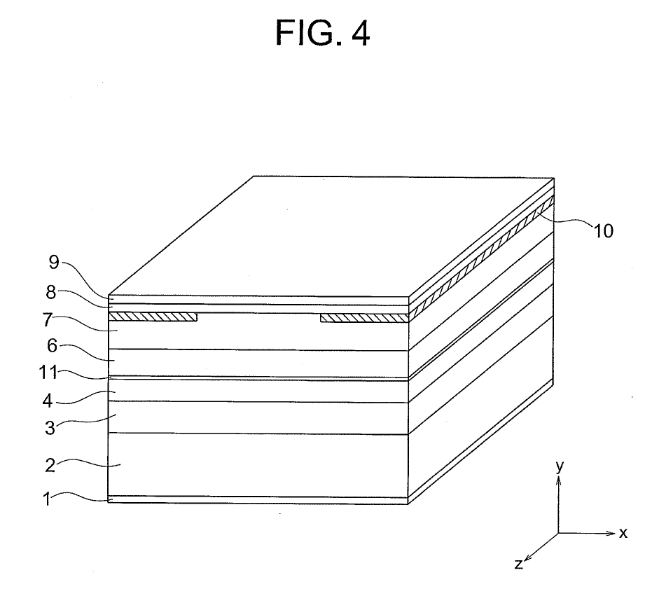

FIG. 4 is a perspective view illustrating a semiconductor laser device having an oscillation wavelength of approximately 920 nm according to Embodiment 2 of the present invention. In FIG. 4, reference numeral 11 denotes an InₘGa₁₋ₘAs active layer (with a layer thickness of 12 nm) (hereinafter referred to as active layer 11). Other components are identical with those of FIG. 1, and hence description thereof is omitted here. Note that a structure illustrated in FIG. 4 is different from the structure illustrated in FIG. 1 in that the active layer 11 is provided in place of the active layer 5 of FIG. 1.

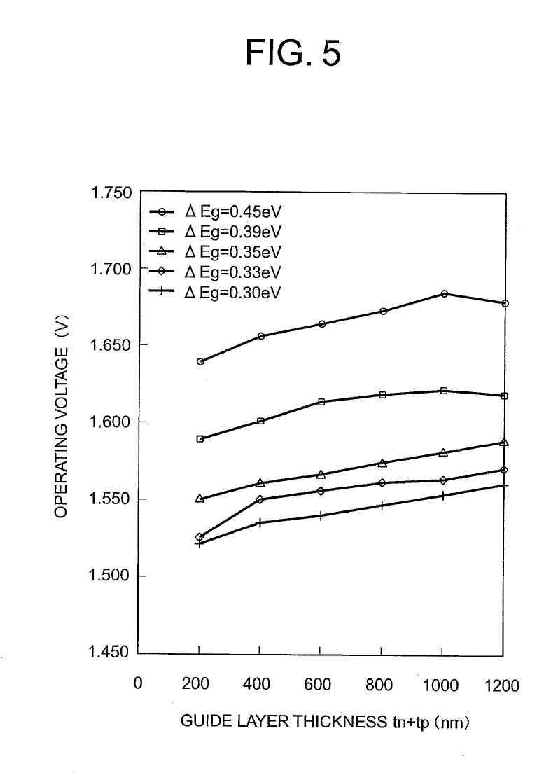

An operating voltage with an injection current of 24 mA is determined in each case where an In composition ratio m of the active layer 11 and the As composition ratio y of the n-type and p-type cladding layer side guide layers 4 and 6 are varied to change a band gap energy difference ΔEg, which is a difference between a band gap energy of the active layer 11 and the band gap energy of the n-type and p-type cladding layer side guide layers 4 and 6, and change the layer thickness to of the n-type cladding layer side guide layer 4 and the layer thickness tp of the p-type cladding layer side guide layer 6. Results of the determination are illustrated in FIG. 5.

It is found from FIG. 5 that when the band gap energy difference ΔEg is 0.35 eV or less, the operating voltage itself becomes lower. In Embodiment 1, when ΔEg is 0.3 eV or less, the operating voltage becomes lower, while in this embodiment, the operating voltage becomes lower when ΔEg is 0.35 eV or less. The reason for this difference may be that, because the active layer of this embodiment is different from that of FIG. 1, a difference in strain or band offset ratio has exerted an influence. However, also in this embodiment, the operating voltage may be reduced securely by setting the band gap energy difference ΔEg to 0.3 eV or less. Taking the need for effectively confining carriers within the active layer 11 into consideration, a lower limit of the band gap energy difference ΔEg is approximately 0.1 eV.

Note that also in this embodiment, the case where the sum (tn+tp) of the layer thicknesses of the n-type and p-type cladding layer side guide layers 4 and 6 is set to 200 nm or more is taken as an example. However, from a viewpoint that 80% or more of light should be confined to the n-type and p-type cladding layer side guide layers 4 and 6 to thereby suppress the influence of free carrier absorption in the n-type and p-type cladding layers 3 and 7, it is preferable that the sum (tn+tp) of the layer thicknesses of the n-type and p-type cladding layer side guide layers 4 and 6 be set to be half an oscillation wavelength or more, that is, 460 nm or more. Note that an upper limit of the sum (tn+tp) of the layer thicknesses of the n-type and p-type cladding layer side guide layers 4 and 6 is several pm, which corresponds to a diffusion length of carriers.

In this way, also in this embodiment, the same effects as those in Embodiment 1 described above can be obtained.

As described in Embodiments 1 and 2, the operating voltage of the semiconductor laser device according to the present invention is defined by a relationship between the band gap energy difference ΔEg, which is the difference between the band gap energy of the active layer 5 or 11 and the band gap energy of the n-type and p-type cladding layer side guide layers 4 and 6, and the layer thicknesses to and tp of the n-type and p-type cladding layer side guide layers 4 and 6. Therefore, though the semiconductor laser devices having oscillation wavelengths of approximately 810 nm and 920 nm have been respectively exemplified in Embodiments 1 and 2, the present invention is not limited thereto, and the effects of the present invention are also exerted on semiconductor laser devices having other wavelength bands and semiconductor laser devices made of other material systems.

Further, though fixed values of the layer thicknesses of the active layers 5 and 11 and fixed values of the compositions and layer thicknesses of the n-type and p-type cladding layers 3 and 7 have been exemplified in Embodiments 1 and 2, those values are merely examples. It is needless to say that the present invention is not limited thereto.

Further, though the proton injection method is employed as a current confinement method for improving oscillation efficiency in Embodiments 1 and 2, the present invention is not limited thereto. It is needless to say that the improvement of oscillation efficiency can be achieved by a method using insulating films, a method using a waveguide, such as a ridge formation, a method involving inserting a current blocking layer including embedding an n-GaAs semiconductor layer, or the like. Moreover, a layer thickness of the proton injection region 10 and a range thereof are merely examples, and the present invention is not limited thereto.

Note that the inventor (s) of the present invention found out for the first time that, when the sum of the layer thicknesses of the n-type and p-type cladding layer side guide layers 4 and 6 is as thick as 200 nm or more, and when the n-type and p-type cladding layer side guide layers 4 and 6 are not intentionally doped so as to be in an undoped state or a doped state close to the undoped state, the turn-on voltage Vj can be lowered by setting the band gap energy difference ΔEg, which is the difference between the band gap energy of the active layer 5 or 11 and the band gap energy of the n-type and p-type cladding layer side guide layers 4 and 6 to 0.3 eV or less.

1. A semiconductor laser device, comprising:
a p-type cladding layer;
a p-type cladding layer guide layer;
an active layer;
an n-type cladding layer guide layer; and
an n-type cladding layer, wherein
each of the p-type cladding layer guide layer and the n-type cladding layer guide layer is undoped or close to undoped,
sum of thickness of the p-type cladding layer guide layer and thickness of the n-type cladding layer guide layer is at least 200 nm, and
both of (i) difference between band gap energy of the p-type cladding layer guide layer and band gap energy of the active layer and (ii) difference between band gap energy of the n-type cladding layer guide layer and the band gap energy of the active layer do not exceed 0.3 eV.

2. A semiconductor laser device, comprising:
a p-type cladding layer;
a p-type cladding layer guide layer;
an active layer;
an n-type cladding layer guide layer; and
an n-type cladding layer, wherein
each of the p-type cladding layer guide layer and the n-type cladding layer guide layer is undoped or close to undoped,
sum of thickness of the p-type cladding layer guide layer and thickness of the n-type cladding layer guide layer is at least 200 nm,
oscillation wavelength of the semiconductor laser device is approximately 810 nm, and
both of (i) difference between band gap energy of the p-type cladding layer guide layer and band gap energy of the active layer, and (ii) difference between band gap energy of the n-type cladding layer guide layer and the band gap energy of the active layers do not exceed 0.3 eV.

3. A semiconductor laser device, comprising:
a p-type cladding layer;
a p-type cladding layer guide layer;
an active layer;
an n-type cladding layer guide layer; and
an n-type cladding layer, wherein
each of the p-type cladding layer guide layer and the n-type cladding layer guide layer is undoped or close to undoped,
sum of thickness of the p-type cladding layer guide layer and thickness of the n-type cladding layer guide layer is at least 200 nm,
oscillation wavelength of the semiconductor laser device is approximately 920 nm, and
both of (i) difference between band gap energy of the p-type cladding layer guide layer and band gap energy of the active layer, and (ii) difference between band gap energy of the n-type cladding layer guide layer and the band gap energy of the active layer do not exceed 0.3 eV.
